(19) United States
(12) Patent Application Publication
(10) Pub. No.: US 2022/0293669 A1
(43) Pub. Date: Sep. 15, 2022

(54) DISPLAY APPARATUS AND METHOD OF MANUFACTURING THE SAME

(71) Applicant: SAMSUNG ELECTRONICS CO., LTD., Suwon-si (KR)

(72) Inventors: Joonyong PARK, Suwon-si (KR); Dongho KIM, Seoul (KR); Hyunjoon KIM, Seoul (KR); Seogwoo HONG, Yongin-si (KR); Kyungwook HWANG, Seoul (KR); Junsik HWANG, Hwaseong-si (KR)

(73) Assignee: SAMSUNG ELECTRONICS CO., LTD., Suwon-si (KR)

(21) Appl. No.: 17/525,587

(22) Filed: Nov. 12, 2021

Related U.S. Application Data
(60) Provisional application No. 63/161,142, filed on Mar. 15, 2021.

(30) Foreign Application Priority Data
Jun. 4, 2021 (KR) 10-2021-0072971

(51) Int. Cl. H01L 27/15; H01L 33/00; H01L 33/50; H01L 33/58

(52) U.S. Cl. CPC H01L 27/156; H01L 33/005; H01L 33/502; H01L 33/58; H01L 2933/0041; H01L 2933/0058; B82Y 20/00

(57) ABSTRACT

A display apparatus includes a driving substrate including a plurality of grooves, micro light-emitting devices provided in the plurality of grooves and configured to emit light of a first color, and a color conversion layer provided on the micro light-emitting devices and configured to convert the light of the first color into light of at least one second color, wherein the color conversion layer includes light blocking patterns spaced apart from the micro light-emitting devices and spaced apart from each other on a same plane, a nano-porous layer provided between adjacent ones of the light blocking patterns, spaced apart from the micro light-emitting devices, and including a plurality of nano-pores, and quantum dots impregnated in the nano-porous layer and configured to convert the light of the first color into the light of the at least one second color.

### CROSS-REFERENCE TO RELATED APPLICATIONS

This application is based on and claims priority under 35 U.S.C. § 119 to U.S. Provisional Application No. 63/161,142, filed on Mar. 15, 2021, in the United States Patent and Trademark Office, and Korean Patent Application No. 10-2021-0072971, filed on Jun. 4, 2021, in the Korean Intellectual Property Office, the disclosures of which are incorporated by reference herein in their entirety.

### BACKGROUND

### 1. Field

The disclosure relates to a display apparatus and a method of manufacturing the same.

### 2. Description of Related Art

There are multiple methods of realizing full colors in a display apparatus using a micro light-emitting device.

First, there is a method of locating micro light-emitting devices emitting red light, green light, and blue light in sub-pixels and then realizing a color of a pixel through color mixing. This is the structurally simplest method and may enable a display apparatus to be manufactured by locating a micro light-emitting device emitting red light, a micro light-emitting device emitting green light, and a micro light-emitting device emitting blue light at sub-pixel positions on a driving substrate. However, this method may have a problem in that uniformity is reduced because it is difficult to control a concentration of indium (In) that is used as a material of micro light-emitting devices currently emitting green light and red light. Also, this method may have problems in that a color shift occurs according to a temperature of a micro light-emitting device emitting red light, and a complexity in a manufacturing process may increase because three types of transistors need to be arranged due to a difference in a turn-on voltage and efficiency of micro light-emitting devices emitting different colors in a driving circuit, thereby resulting in more serious problems in micro light-emitting devices.

Further, there is a method of causing emission of white light by using a light conversion material in a light-emitting device package emitting blue light or ultraviolet light, converting the white light into red light, green light, and blue light through a color filter array in each sub-pixel, and emitting the red light, the green light, and the blue light. This method may have problems in that it is difficult to perform a micro light-emitting device packaging process for emitting white light as a size of a device such as a micro light-emitting device decreases, and the distribution of light is not uniform because an interval in which a fluorescent material for white light conversion of a micro light-emitting device exhibits highest efficiency is fixed. Also, because a color filter array is configured to block colors other than a corresponding color, about ⅔ of the total amount of light is lost.

Further still, there is a method of using a micro light-emitting device emitting blue light, and locating a color conversion layer using quantum dots for converting blue light into red light or green light in a sub-pixel. However, this method has problems in that as an interval between quantum dots decreases, nonradiative transfer increases due to exciton quenching, electron coupling, etc. and thus light loss increases. This method has problems in that, although research on a method of dispersing quantum dots in a transparent polymer has been conducted to reduce nonradiative transfer, because most of blue light is not absorbed by quantum dots, light conversion efficiency (LCE) is reduced and unabsorbed blue light is mixed with red light or green light. Accordingly, although a method of increasing a thickness of a color conversion layer using a transparent polymer has been considered to increase an absorbance of blue light by the color conversion layer, image quality deteriorates and a total thickness of a display apparatus increases.

### SUMMARY

Provided are a display apparatus and a method of manufacturing the same which may include a micro light-emitting device emitting blue light and a color conversion layer having quantum dots for converting blue light into red light and green light, and may minimize quenching of the quantum dots and may increase an absorbance of the quantum dots for blue light.

Additional aspects will be set forth in part in the description which follows and, in part, will be apparent from the description, or may be learned by practice of presented embodiments.

In accordance with an aspect of an example embodiment, a display apparatus includes a driving substrate including a plurality of grooves; a plurality of micro light-emitting devices arranged in the plurality of grooves, the plurality of micro light-emitting devices being configured to emit light of a first color; and a color conversion layer on the plurality of micro light-emitting devices, the color conversion layer being configured to convert the light of the first color into light of at least one second color, wherein the color conversion layer includes a plurality of light blocking patterns spaced apart from the plurality of micro light-emitting devices, the plurality of light blocking patterns being spaced apart from each other on a same plane, a nano-porous layer between adjacent ones of the plurality of light blocking patterns, the nano-porous layer being spaced apart from the plurality of micro light-emitting devices and including a plurality of nano-pores, and a plurality of quantum dots impregnated in the nano-porous layer, the plurality of quantum dots being configured to convert the light of the first color into the light of the at least one second color.

The light of the first color may include blue light, and the light of the at least one second color may include red light and green light.

The plurality of quantum dots may include a plurality of first quantum dots configured to convert the blue light into the red light, and a plurality of second quantum dots configured to convert the blue light into the green light, and the nano-porous layer may include a first area in which the plurality of first quantum dots are impregnated, and a second area in which the plurality of second quantum dots are impregnated.

The nano-porous layer may include a third area through which the blue light is transmitted.

The nano-porous layer may include a plurality of nano-particles, and shapes of the plurality of nano-pores may be defined by adjacent nano-particles.

A size of each of the plurality of nano-pores may be in a range from ⅕ to 1/20 of a wavelength of the light of the first color.

A size of each of the plurality of nano-pores may be in a range from 10 nm to 50 nm.

A material of the nano-porous layer may include at least one from among titanium oxide (TiO₂), zinc oxide (ZnO), barium peroxide (BaO₂), glass, silicon oxide (SiOx), gallium nitride (GaN), indium gallium nitride (InGaN), and a transparent polymer material.

The display apparatus may further include a transparent layer located between the plurality of micro light-emitting devices and the color conversion layer, the transparent layer being configured to transmit the light of the first color.

A thermal conductivity of the transparent layer may be equal to or less than 1 W/mK.

In accordance with an aspect of an example embodiment, a method of manufacturing a display apparatus includes forming a color conversion layer on a plurality of micro light-emitting devices configured to emit blue light, the color conversion layer including a red area where the blue light is converted into red light, a green area where the blue light is converted into green light, and a blue area where the blue light is transmitted, wherein the forming of the color conversion layer includes forming, on a base substrate, a plurality of light blocking patterns for distinguishing the red area, the green area, and the blue area, and a nano-porous layer having a plurality of nano-pores, the nano-porous layer including a first area, a second area, and a third area respectively corresponding to the red area, the green area, and the blue area; impregnating a plurality of first quantum dots for converting the blue light into the red light in the first area, and a plurality of second quantum dots for converting the blue light into the green light in the second area; and covering a top surface of the nano-porous layer with a transparent layer.

The forming of the nano-porous layer may include applying a solution including a plurality of nano-particles to the first area, the second area, and the third area, and performing heat treatment at a temperature of 100° C. to 300° C. for evaporation of the applied solution and sintering of the plurality of nano-particles.

The impregnating of the plurality of first quantum dots and the plurality of second quantum dots may include providing the plurality of first quantum dots to the first area of the nano-porous layer, using inkjet printing, and providing the plurality of second quantum dots to the second area of the nano-porous layer, using inkjet printing.

A diameter of each of the plurality of nano-pores may be in a range from ⅕ to 1/20 of a wavelength of the blue light.

A size of each of the plurality of nano-pores may be in a range from 10 nm to 50 nm.

A material of the nano-porous layer may include at least one from among titanium oxide (TiO₂), zinc oxide (ZnO), barium peroxide (BaO₂), glass, silicon oxide (SiOx), gallium nitride (GaN), indium gallium nitride (InGaN), and a transparent polymer material.

The transparent layer may have a thermal conductivity equal to or less than 1 W/mK.

The method may further include arranging the plurality of micro light-emitting devices in a plurality of grooves of a driving substrate; and locating the color conversion layer on the plurality of micro light-emitting devices, wherein the locating of the color conversion layer includes locating the color conversion layer so that the transparent layer faces the plurality of micro light-emitting devices.

The arranging of the plurality of micro light-emitting devices in the plurality of grooves may include a fluidic self-assembly method.

The arranging of the plurality of micro light-emitting devices in the plurality of grooves may include arranging the plurality of micro light-emitting devices in a plurality of grooves of a transfer substrate using the fluidic self-assembly method, and transferring the plurality of micro light-emitting devices arranged in the plurality of grooves of the transfer substrate to the plurality of grooves of the driving substrate.

### BRIEF DESCRIPTION OF THE DRAWINGS

The above and other aspects, features, and advantages of certain example embodiments will be more apparent from the following description taken in conjunction with the accompanying drawings, in which:

FIG. 1 is a conceptual view illustrating a display apparatus, according to an example embodiment;

FIG. 2 is a view for describing a color conversion layer of FIG. 1;

FIG. 3 is a flowchart for describing a method of manufacturing a display apparatus, according to an example embodiment;

FIGS. 4A and 4B are views for describing an example embodiment of arranging micro light-emitting devices, by using a fluidic self-assembly method;

FIGS. 5A, 5B, and 5C are views for describing an example embodiment of arranging micro light-emitting devices, by using a fluidic self-assembly method;

FIG. 6 is a view for describing a process of locating a color conversion layer on a driving substrate;

FIGS. 7, 8, and 9A through 9C are views for describing a process of manufacturing a color conversion layer, according to an example embodiment;

FIG. 10 is a block diagram illustrating an electronic device, according to an example embodiment;

FIG. 11 is a view illustrating an example where a display apparatus is applied to a mobile device, according to an example embodiment;

FIG. 12 is a view illustrating an example where a display apparatus is applied to a display apparatus for vehicle, according to an example embodiment;

FIG. 13 is a view illustrating an example where a display apparatus is applied to augmented reality glasses, according to an example embodiment;

FIG. 14 is a view illustrating an example where a display apparatus is applied to a signage, according to an example embodiment; and

FIG. 15 is a view illustrating an example where a display apparatus is applied to a wearable display, according to an example embodiment.

### DETAILED DESCRIPTION

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, the example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a display apparatus and a method of manufacturing the same according to various example embodiments will be described with reference to the accompanying drawings. Like reference numerals denote like elements throughout, and in the drawings, sizes of elements may be exaggerated for clarity and convenience of explanation. It will be understood that although the terms “first,” “second,” etc. may be used herein to describe various elements, these elements should not be limited by these terms. These terms are only used to distinguish one element from another.

The singular forms “a,” “an,” and “the” are intended to include the plural forms as well, unless the context clearly indicates otherwise. When a portion “includes” an element, another element may be further included, rather than excluding the existence of the other element, unless otherwise described. Sizes or thicknesses of elements may be exaggerated for clarity of explanation. It will also be understood that when a material layer is referred to as being “on” another layer or a substrate, the material layer may be directly on the other layer or the substrate, or intervening layers may also be present therebetween. A material of each layer in the following embodiments is an example, and thus other materials may be used.

Specific execution methods described in the disclosure are examples, and a technical scope is not limited by any method. For the sake of brevity, conventional electronics, control systems, software, and other functional aspects of the systems may not be described in detail. Also, lines or members connecting elements illustrated in the drawings are merely illustrative of functional connections and/or physical or circuit connections. In an actual device, the connections between components may be represented by various functional connections, physical connections, or circuit connections that are replaceable or added.

The use of the terms “a” and “an,” and “the” and similar referents in the disclosure is to be construed to cover both the singular and the plural.

The steps of all methods described herein may be performed in any suitable order unless otherwise indicated herein or otherwise clearly contradicted by context. The use of any and all examples, or exemplary language (e.g., “such as”) provided herein, is intended merely to better illuminate the disclosure and does not pose a limitation on the scope of the disclosure unless otherwise claimed.

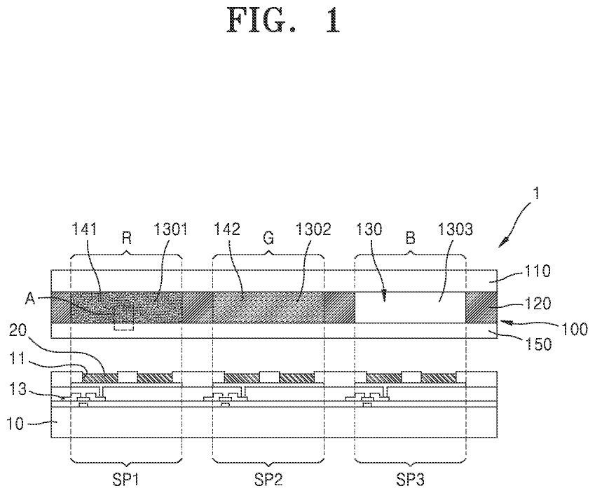

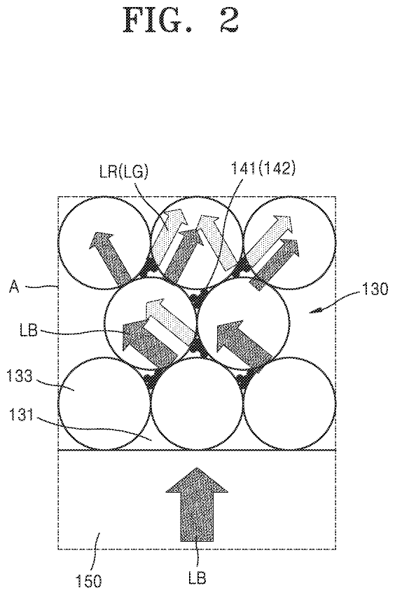

FIG. 1 is a conceptual view illustrating a display apparatus 1, according to an example embodiment. FIG. 2 is an enlarged view illustrating a portion A of FIG. 1, for describing a color conversion layer 100 of the display apparatus 1 of FIG. 1.

Referring to FIG. 1, the display apparatus 1 according to an example embodiment includes a driving substrate 10, a micro light-emitting device 20 located on the driving substrate 10, and the color conversion layer 100 located on the micro light-emitting device 20.

The driving substrate 10 includes a plurality of grooves 11. Each of the grooves 11 may have a size that allows the micro light-emitting device 20 to be inserted into the groove 11.

The driving substrate 10 may include a plurality of sub-pixel areas SP1, SP2, and SP3. The plurality of sub-pixel areas SP1, SP2, and SP3 may include a first sub-pixel area SP1, a second sub-pixel area SP2, and a third sub-pixel area SP3.

A plurality of grooves 11 may be located in each of the first through third sub-pixel areas SP1, SP2, and SP3. For example, two grooves 11 may be provided in each of the first through third sub-pixel areas SP1, SP2, and SP3. A micro light-emitting device 20 may be located in each of the two grooves 11.

As two grooves 11 are located in each of the first through third sub-pixel areas SP1, SP2, and SP3, if a micro light-emitting device 20 is omitted in one groove 11 in a manufacturing process, another micro light-emitting device 20 may be provided in the other groove 11, thereby reducing an error rate and omitting a repair process.

However, the number of grooves 11 located in each of the first through third sub-pixel areas SP1, SP2, and SP3 is not limited thereto, and may be 1, or 3 or more.

The driving substrate 10 may include a thin-film transistor 13 for driving the micro light-emitting device 20 to be described below. Although other elements for operating the micro light-emitting device 20 may be included in the driving substrate 10, the other elements are common in the art and illustrations and descriptions thereof will be omitted.

The micro light-emitting device 20 that emits light of a first color is located in the groove 11 of the driving substrate 10. A plurality of micro light-emitting devices 20 are respectively arranged in the plurality of grooves 11. Light LB of the first color may be blue light (see, e.g., FIG. 2).

The plurality of micro light-emitting devices 20 may emit blue light, in a state where the plurality of micro light-emitting devices 20 are respectively aligned in the plurality of grooves 11.

The color conversion layer 100 may be located on the micro light-emitting devices 20, and may convert the light LB of the first color emitted by the micro light-emitting devices into light LR or LG of a second color. The second color may be at least one second color and is different from the first color.

For example, when light emitted by the micro light-emitting devices 20 is blue light, a portion of the color conversion layer 100 may convert the blue light into red light, and another portion of the color conversion layer 100 may convert the blue light into green light.

The color conversion layer 100 includes a red area R that converts the blue light into red light, a green area G that converts the blue light into green light, and a blue area B that transmits the blue light therethrough.

The color conversion layer 100 includes light blocking patterns 120 spaced apart from each other on the same plane, a nano-porous layer 130 located between adjacent ones of the light blocking patterns 120, and first and second quantum dots 141 and 142 impregnated in areas of the nano-porous layer 130.

The light blocking patterns 120 may be spaced apart from the micro light-emitting devices 20, and may be spaced apart from each other on the same plane to distinguish the red area R, the green area G, and the blue area B.

The light blocking patterns 120 may include a material that blocks light. For example, the light blocking patterns 120 may include an ultraviolet-cured acrylic resin, a urethane resin, or an epoxy resin including a black pigment/dye.

Referring to FIGS. 1 and 2, the nano-porous layer 130 may be spaced apart from the micro light-emitting devices 20, and may have a porous structure having a plurality of nano-pores 131. Because the nano-porous layer 130 is spaced apart from the micro light-emitting devices 20, if a temperature of a light-emitting device increases in a process of emitting light, the degradation of the color conversion layer 100 due to the light-emitting device may be reduced.

The nano-porous layer 130 may minimize the aggregation of the impregnated first and second quantum dots 141 and 142, through the porous structure.

The nano-porous layer 130 may include a plurality of nano-particles 133, to form the nano-pores 131 therein. As shown in FIG. 2, the shapes of the nano-pores 131 may be defined by adjacent nano-particles 133. A size of the nano-particles 133 may be determined by considering a size of the nano-pore 131.

However, the nano-porous layer 130 does not necessarily include the nano-particles 133, and may have any of various structures as longs as the nano-porous layer 130 has the nano-pores 131. For example, the nano-porous layer 130 may be porous glass having the nano-pores 131.

The nano-porous layer 130 may be configured to scatter the light LB of the first color. A size of the nano-pore 131 may be determined by considering a wavelength of the light LB of the first color. For example, a size of the nano-pore 131 may range from ⅕ to 1/20 of a wavelength of the light LB of the first color. For example, a size of the nano-pore 131 may range from 10 nm to 50 nm. A size of the nano-pores 131 may be an average size of the nano-pores 131.

A material of the nano-porous layer 130 may include at least one from among titanium oxide (TiO₂), zinc oxide (ZnO), barium peroxide (BaO₂), glass, silicon oxide (SiOx), gallium nitride (GaN), indium gallium nitride (InGaN), and a transparent polymer material. A material of the nano-particles 133 may include at least one from among titanium oxide (TiO₂), zinc oxide (ZnO), barium peroxide (BaO₂), glass, silicon oxide (SiOx), gallium nitride (GaN), indium gallium nitride (InGaN), and a transparent polymer material. The transparent polymer material may be at least one from among polyimide, silicone resin, acrylic resin, and epoxy resin.

The nano-pores 131 of the nano-porous layer 130 may be formed by dispersing the plurality of nano-particles 133. However, a method of forming the nano-pores 131 of the nano-porous layer 130 is not limited thereto, and may be any of various methods. For example, the nano-pores 131 may be formed by using phase separation etching or electrochemical etching.

The first and second quantum dots 141 and 142 may convert the light LB of the first color into the light LR and LG of the second color.

Each of the first and second quantum dots 141 and 142 may have a core-shell structure including a core portion and a shell portion, or may have a particle structure with no shell. The core-shell structure may have a single shell or multi-shells. The multi-shells may be, for example, double shells.

The first and second quantum dots 141 and 142 may include at least one from among, for example, group II-VI semiconductors, group III-V semiconductors, group IV-VI semiconductors, group IV semiconductors, and graphene quantum dots. The first and second quantum dots 141 and 142 may include at least one from among, for example, but not limited to, cadmium (Cd), selenium (Se), zinc (Zn), sulfur (S), and indium phosphide (InP). Each of the first and second quantum dots 141 and 142 may have a diameter equal to or less than tens of nm, for example, equal to or less than about 10 nm.

The first and second quantum dots 141 and 142 may include the first quantum dots 141 that convert blue light into red light and the second quantum dots 142 that convert blue light into green light. A size of the second quantum dots 142 is different from a size of the first quantum dots 141.

The first and second quantum dots 141 and 142 are impregnated in the nano-porous layer 130. The first and second quantum dots 141 and 142 impregnated in the nano-porous layer 130 may be located in the nano-pores 131, and may be attached to surfaces of the nano-particles 133. The first and second quantum dots 141 and 142 located in one nano-pore 131 may maintain a certain distance from first and second quantum dots 141 and 142 located in another nano-pore 131.

As a certain distance is maintained between the first and second quantum dots 141 and 142, a decrease in quantum yield due to quenching, which occurs when the first and second quantum dots 141 and 142 are continuously arranged, may be prevented. Also, as the nano-porous layer 130 has the nano-pores 131 having a certain size and scattering of the light LB of the first color is caused, more first and second quantum dots 141 and 142 may be excited, thereby improving color conversion efficiency. Although the red area R of the color conversion layer 100 is illustrated in FIG. 2, the green area G may operate similarly.

The first quantum dots 141 are impregnated in a first area 1301 of the nano-porous layer 130 located in the red area R, and the second quantum dots 142 are impregnated in a second area 1302 of the nano-porous layer 130 located in the green area G. The first and second quantum dots 141 and 142 may not be impregnated in a third area 1303 of the nano-porous layer 130 located in the blue area B. In the first area 1301, blue light emitted by the micro light-emitting devices 20 is scattered by the nano-particles 133 and is converted into red light by first quantum dots 141 and emitted. In the second area 1302, blue light emitted by the micro light-emitting devices 20 is scattered by the nano-particles 133 and is converted into green light by second quantum dots 142 and emitted. In the third area 1303, blue light emitted by the micro light-emitting devices 20 is emitted without color conversion.

A transparent layer 150 that transmits the light LB of the first color may be located between the color conversion layer 100 and the micro light-emitting devices 20.

The transparent layer 150 may transmit the light LB of the first color emitted by the micro light-emitting devices 20, but may block heat transfer from the micro light-emitting devices 20 to the color conversion layer 100. For example, the transparent layer 150 may have a thermal conductivity equal to or less than 1 W/mK.

A base substrate 110 may be located on the color conversion layer 100. The base substrate 110 may transmit light emitted through the nano-porous layer 130. The base substrate 110 may be a transparent substrate. For example, the base substrate 110 may be a transparent glass substrate or a transparent plastic substrate.

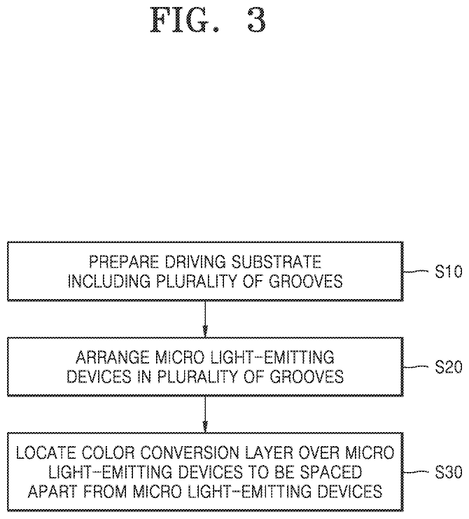

FIG. 3 is a flowchart for describing a method of manufacturing the display apparatus 1, according to an example embodiment.

Referring to FIG. 3, in the method of manufacturing the display apparatus 1 according to an example embodiment, first, the driving substrate 10 including a plurality of grooves 11 is prepared (S10).

The driving substrate 10 includes the plurality of grooves 11. Each groove 11 may have a size that allows a micro light-emitting device 20 to be inserted into the groove 11.

The driving substrate 10 may include a plurality of sub-pixel areas SP1, SP2, and SP3. The plurality of sub-pixel areas SP1, SP2, and SP3 include the first sub-pixel area SP1, the second sub-pixel area SP2, and the third sub-pixel area SP3.

A plurality of grooves 11 may be located in each of the first through third sub-pixel areas SP1, SP2, and SP3. For example, two grooves 11 may be provided in each of the first through third sub-pixel areas SP1, SP2, and SP3.

The micro light-emitting devices 20 emitting light of a first color are arranged in the plurality of grooves 11 (S20). In order to arrange the micro light-emitting devices 20 at certain intervals, a fluidic self-assembly method may be used.

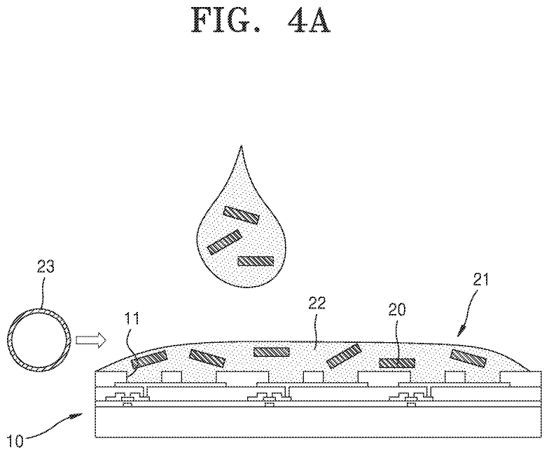

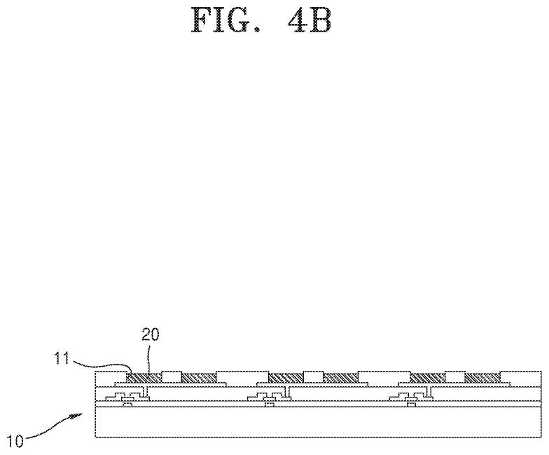

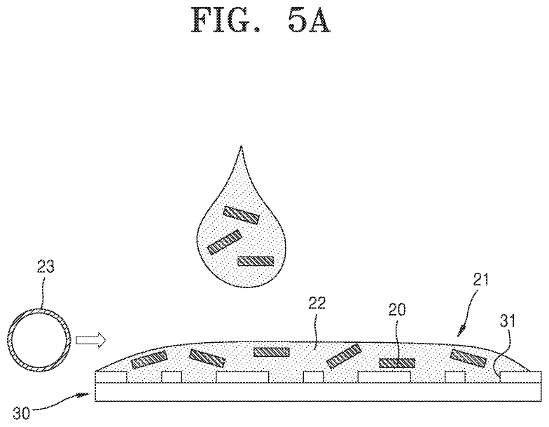

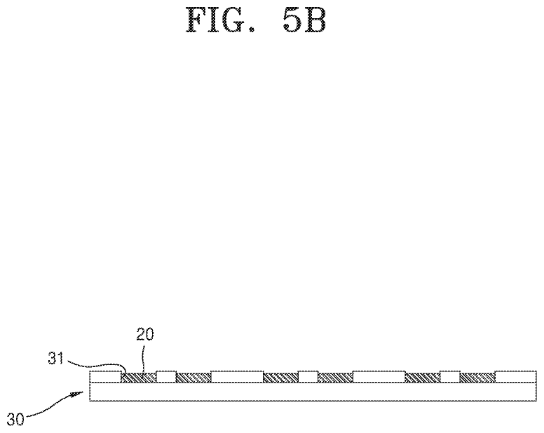

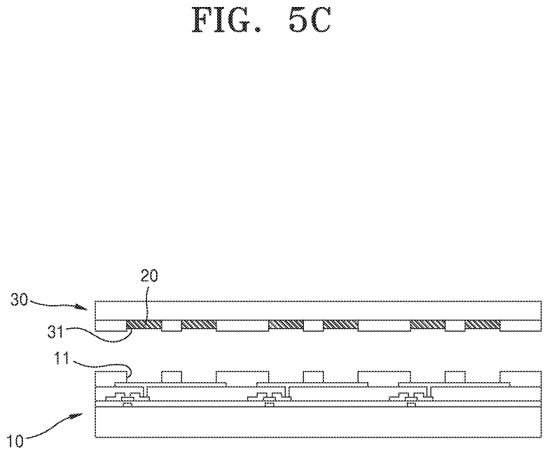

FIGS. 4A and 4B are views for describing an example embodiment of arranging the micro light-emitting devices 20, by using a fluidic self-assembly method without a transfer substrate. FIGS. 5A, 5B, and 5C are views for describing an example embodiment of arranging the micro light-emitting devices 20, by using a fluidic self-assembly method with a transfer substrate.

For example, as shown in FIG. 4A, a suspension 21 including the micro light-emitting devices 20 and a liquid 22 is supplied to the driving substrate 10, and the micro light-emitting devices 20 are aligned in the grooves 11 of the driving substrate 10 by using a pressing member 23. Next, as shown in FIG. 4B, the liquid 22 may be removed, and the micro light-emitting devices 20 may be arranged in the grooves 11 of the driving substrate 10.

In an example embodiment, as shown in FIG. 5A, the suspension 21 including the micro light-emitting devices 20 and the liquid 22 is supplied to a transfer substrate 30, and the micro light-emitting devices 20 are aligned in grooves 31 of the transfer substrate 30. Next, as shown in FIG. 5B, the liquid 22 is removed, and the micro light-emitting devices 20 are arranged in the grooves 31 of the transfer substrate 30. Next, as shown in FIG. 5C, the grooves 31 of the transfer substrate 30 may be aligned with the grooves 11 of the driving substrate 10, and the micro light-emitting devices 20 arranged in the grooves 31 of the transfer substrate 30 may be transferred to the grooves 11 of the driving substrate 10.

In addition, the micro light-emitting devices 20 may be arranged in the grooves 11 of the driving substrate 10, by using various fluidic self-assembly methods.

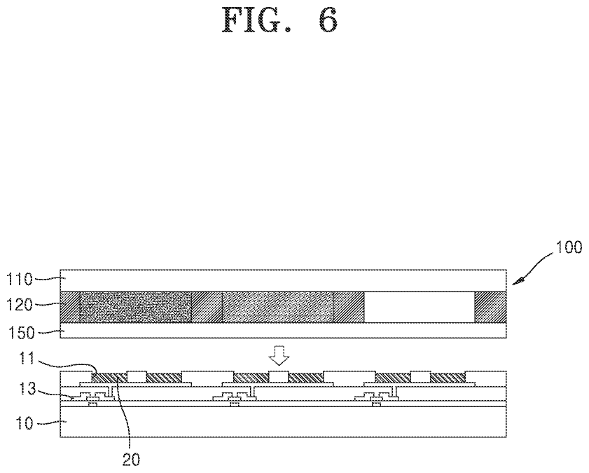

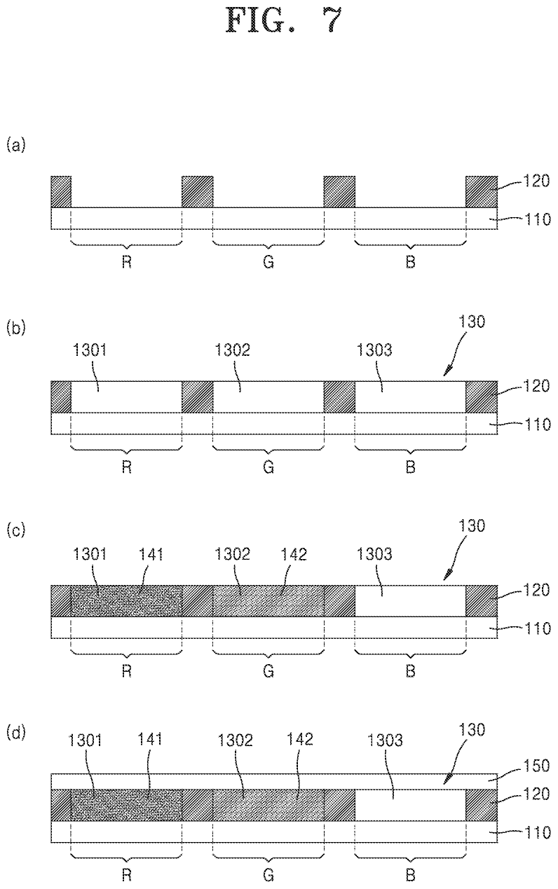

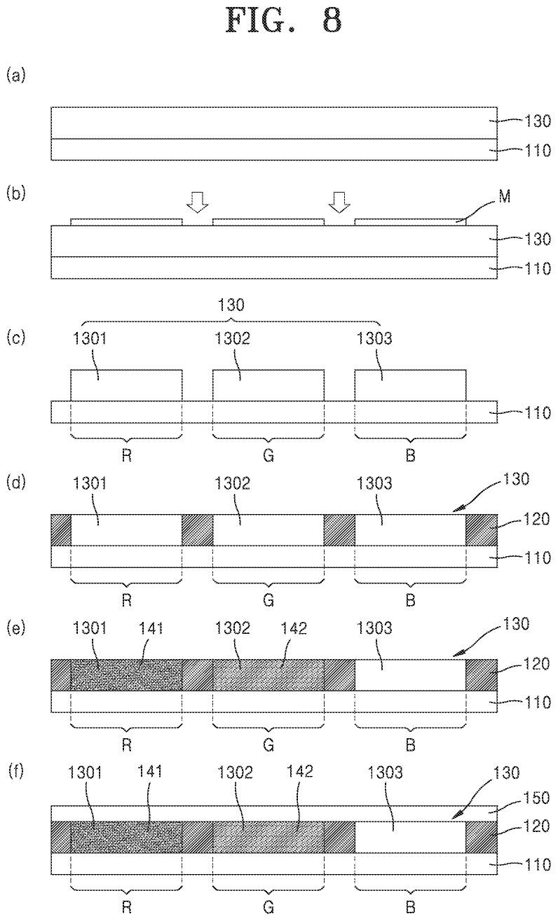

FIG. 6 is a view for describing a process of locating the color conversion layer 100 on the driving substrate 10. FIGS. 7 and 8 are views for describing a process of manufacturing the color conversion layer 100, according to an example embodiment.

Referring to FIGS. 3 and 6, the color conversion layer 100 is located over the micro light-emitting devices 20 to be spaced apart from the micro light-emitting devices 20 (S30). For example, when the color conversion layer 100 is located, the color conversion layer 100 may be located so that the transparent layer 150 of the color conversion layer 100 faces the micro light-emitting devices 20.

Because the color conversion layer 100 is located after the micro light-emitting devices 20 are arranged, a decrease in efficiency in the first and second quantum dots 141 and 142 of the color conversion layer 100 when the micro light-emitting devices 20 are arranged may be prevented.

When the color conversion layer 100 is located on the micro light-emitting devices 20 before the micro light-emitting devices 20 are arranged, efficiency in the first and second quantum dots 141 and 142 of the color conversion layer 100 may be reduced due to the liquid 22 supplied during a fluidic self-assembly method when the micro light-emitting devices 20 are arranged.

In contrast, according to a method of manufacturing the display apparatus 1 according to an example embodiment, because the color conversion layer 100 is located after the micro light-emitting devices 20 are arranged, a decrease in efficiency when the first and second quantum dots 141 and 142 of the color conversion layer 100 are exposed to the liquid 22 may be prevented.

Also, because the color conversion layer 100 is located after the micro light-emitting devices 20 are arranged, an operation of manufacturing the color conversion layer 100 may be performed separately from an operation of manufacturing the micro light-emitting devices 20. Accordingly, the nano-porous layer 130 of the color conversion layer 100 may be freely selected by considering light-scattering characteristics, regardless of a material of the micro light-emitting devices 20.

Referring to FIGS. 7 and 8, in an operation of manufacturing the color conversion layer 100, the light blocking patterns 120 for distinguishing the red area R, the green area G, and the blue area B, and the nano-porous layer 130 having the plurality of nano-pores 131 and including the first area 1301, the second area 1302, and the third area 1303 respectively corresponding to the red area R, the green area G, and the blue area B may be formed on the base substrate 110.

In an operation of forming the nano-porous layer 130, a solution containing the nano-particles 133 is applied to the base substrate 110. As shown in (a) and (b) of FIG. 7, when the light blocking patterns 120 are located on the base substrate 110, the solution containing the nano-particles 133 is applied to the red area R, the green area G, and the blue area B. As shown in (a) through (c) of FIG. 8, before the light blocking patterns 120 are formed on the base substrate 110, the solution containing the nano-particles 133 may be entirely applied to the base substrate 110, and a portion may be removed through patterning using a mask.

After the solution containing the nano-particles 133 is applied, post-treatment is performed. The nano-particles 133 may be applied by using a spin coating method, an inkjet method, a screen printing method, a blade coating method, or the like. Examples of a solvent of the solution may include acetyl alcohol, toluene, and water. In the post-treatment, heat treatment may be performed at a temperature of 100° C. to 300° C. for evaporation of the applied solution and sintering of the nano-particles 133. The heat treatment may be performed for 10 minutes to 10 hours.

An order in which the light blocking patterns 120 and the nano-porous layer 130 are formed may vary. For example, the light blocking patterns 120 may be formed and then the nano-porous layer 130 may be formed as shown in FIG. 7, or the nano-porous layer 130 may be formed and then the light blocking patterns 120 may be formed as shown in FIG. 8.

Referring to (c) of FIG. 7 and (e) of FIG. 8, the first and second quantum dots 141 and 142 may be impregnated in the nano-porous layer 130. In order to impregnate the first and second quantum dots 141 and 142, an inkjet printing method may be used. Due to the inkjet printing method, the first quantum dots 141 may be applied to the first area 1301, and the second quantum dots 142 may be applied to the second area 1302. Because the first and second quantum dots 141 and 142 may be selectively supplied only to required areas through the inkjet printing method, even with a small amount of first and second quantum dots 141 and 142, the first and second quantum dots 141 and 142 may be impregnated in respective areas of the nano-porous layer 130.

Referring to (d) of FIG. 7 and (f) of FIG. 8, after the first and second quantum dots 141 and 142 are impregnated in the nano-porous layer 130, the transparent layer 150 covering a top surface of the nano-porous layer 130 is located. The transparent layer 150 may protect the first and second quantum dots 141 and 142 from the outside.

In the above example embodiments, a method of manufacturing the color conversion layer 100 separately from the driving substrate 10 and then locating the color conversion layer 100 on the driving substrate 10 has been described. However, an arrangement of the color conversion layer 100 is not limited thereto, and the color conversion layer 100 may be directly formed on the driving substrate 10 on which light-emitting devices are arranged.

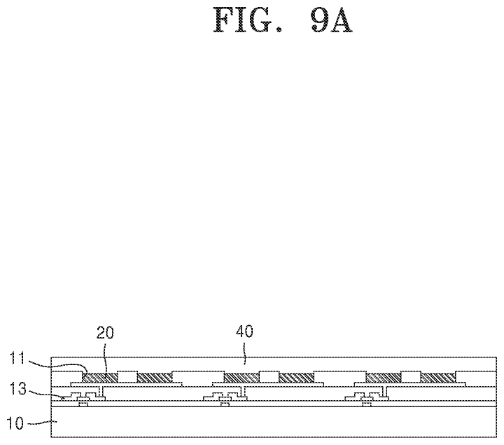

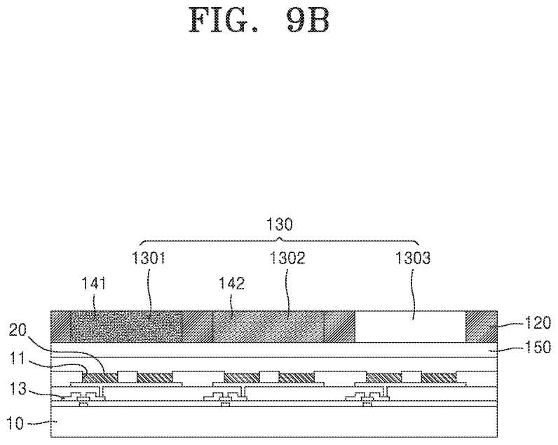

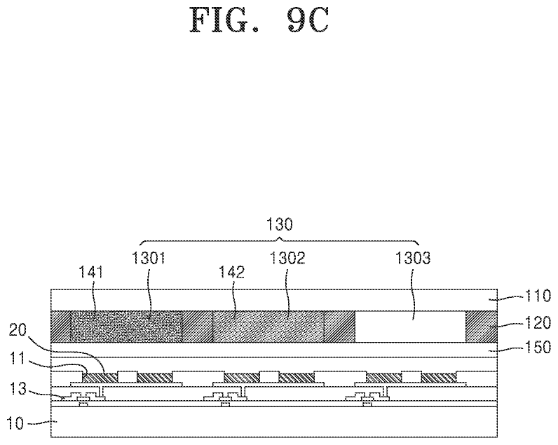

For example, as shown in FIGS. 9A through 9C, a planarization layer 40 may be formed on the driving substrate 10 on which the micro light-emitting devices 20 are arranged in the grooves 11, and the transparent layer 150, the light blocking patterns 120, the nano-porous layer 130, and the base substrate 110 may be sequentially formed on the planarization layer 40.

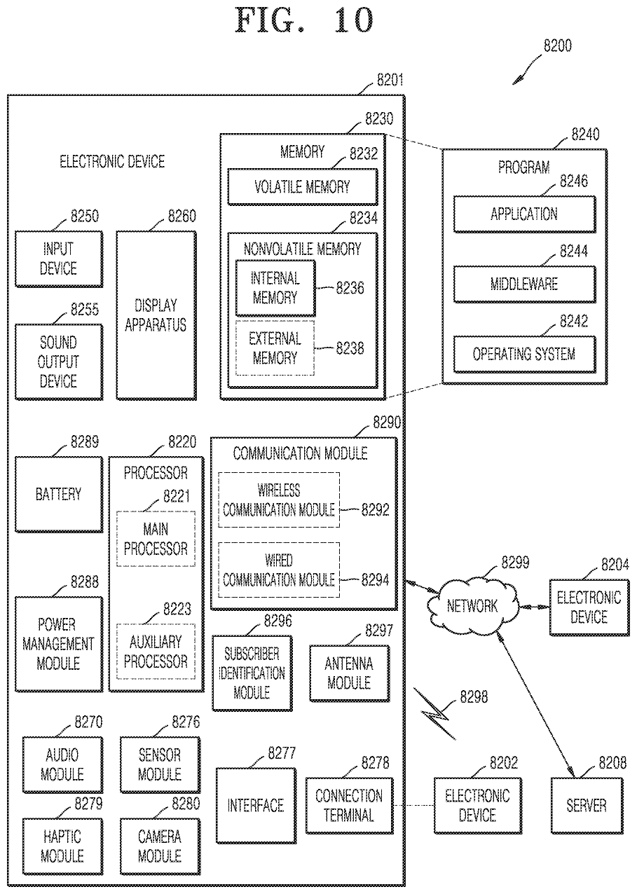

FIG. 10 is a block diagram illustrating an electronic device including a display apparatus, according to an example embodiment.

Referring to FIG. 10, an electronic device 8201 may be provided in a network environment 8200. In the network environment 8200, the electronic device 8201 may communicate with another electronic device 8202 through a first network 8298 (e.g., a short-range wireless communication network), or may communicate with another electronic device 8204 and/or a server 8208 through a second network 8299 (e.g., a long-range wireless communication network). The electronic device 8201 may communicate with the electronic device 8204 through the server 8208. The electronic device 8201 may include a processor 8220, a memory 8230, an input device 8250, a sound output device 8255, a display apparatus 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. Some of the elements may be omitted from the electronic device 8201, or other elements added to the electronic device 8201. Some of the elements may be implemented as one integrated circuit. For example, the sensor module 8276 (e.g., a fingerprint sensor, an iris sensor, or an illuminance sensor) may be embedded in the display apparatus 8260 (e.g., a display).

The processor 8220 may execute software (e.g., a program 8240) to control one or more other elements (e.g., hardware or software elements) from among the electronic device 8201 connected to the processor 8220, and may perform various data processing or operations. As part of the data processing or operations, the processor 8220 may load commands and/or data received from other elements (e.g., the sensor module 8276 and the communication module 8290) into a volatile memory 8232, may process the commands and/or data stored in the volatile memory 8232, and may store resulting data in a nonvolatile memory 8234. The processor 8220 may include a main processor 8221 (e.g., a central processing unit or an application processor) and an auxiliary processor 8223 (e.g., a graphics processing unit, an image signal processor, a sensor hub processor, or a communication processor) which may operate independently or together with the main processor 8221. The auxiliary processor 8223 may use less power than the main processor 8221, and may perform a specialized function.

The auxiliary processor 8223 may operate on behalf of the main processor 8221 while the main processor 8221 is in an inactive state (e.g., a sleep state), or together with the main processor 8221 while the main processor 8221 is in an active state (e.g., an application execution state), to control functions and/or states related to some (e.g., the display apparatus 8260, the sensor module 8276, and the communication module 8290) of the elements of the electronic device 8201. The auxiliary processor 8223 (e.g., an image signal processor or a communication processor) may be implemented as a part of other functionally related elements (e.g., the camera module 8280 and the communication module 8290).

The memory 8230 may store various data required by elements (e.g., the processor 8220 and the sensor module 8276) of the electronic device 8201. The data may include, for example, input data and/or output data for software (e.g., the program 8240) and related commands. The memory 8230 may include the volatile memory 8232 and/or the nonvolatile memory 8234.

The program 8240 may be stored as software in the memory 8230, and may include an operating system 8242, a middleware 8244, and/or an application 8246.

The input device 8250 may receive commands and/or data to be used by an element (e.g., the processor 8220) of the electronic device 8201 from the outside (e.g., a user) of the electronic device 8201. The input device 8250 may include a remote controller, a microphone, a mouse, a keyboard, and/or a digital pen (e.g., a stylus pen).

The sound output device 8255 may output a sound signal to the outside of the electronic device 8201. The sound output device 8255 may include a speaker and/or a receiver. The speaker may be used for general purposes such as multimedia playback or recording playback, and the receiver may be used to receive an incoming call. The receiver may be coupled as a part of the speaker, or may be implemented as an independent separate device.

The display apparatus 8260 may visually provide information to the outside of the electronic device 8201. The display apparatus 8260 may include a display, a hologram device, or a projector, and a control circuit for controlling a corresponding device. The display apparatus 8260 may include the display apparatus 1 described with reference to FIGS. 1 through 9C. The display apparatus 8260 may include touch circuitry configured to sense a touch, and/or a sensor circuit (e.g., a pressure sensor) configured to measure an intensity of a force generated by the touch.

The audio module 8270 may convert sound into an electrical signal, or may convert an electrical signal into sound. The audio module 8270 may obtain sound through the input device 8250, or may output sound through the sound output device 8255 and/or a speaker and/or a headphone of another electronic device (e.g., the electronic device 8202) connected directly or wirelessly to the electronic device 8201.

The sensor module 8276 may detect an operating state (e.g., power or a temperature) of the electronic device 8201 or an external environment state (e.g., a user state), and may generate an electrical signal and/or a data value corresponding to the detected state. The sensor module 8276 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more designated protocols that may be used to directly or wirelessly connect the electronic device 8201 to another electronic device (e.g., the electronic device 8202). The interface 8277 may include a high-definition multimedia interface (HDMI), a universal serial bus (USB) interface, a secure digital (SD) card interface, and/or an audio interface.

A connection terminal 8278 may include a connector through which the electronic device 8201 may be physically connected to another electronic device (e.g., the electronic device 8202). The connection terminal 8278 may include an HDMI connector, a USB connector, an SD card connector, and/or an audio connector (e.g., a headphone connector).

The haptic module 8279 may convert an electrical signal into a mechanical stimulus (e.g., a vibration or a motion) or an electrical stimulus that may be perceived by a user through tactile or kinesthetic sense. The haptic module 8279 may include a motor, a piezoelectric element, and/or an electrical stimulation device.

The camera module 8280 may capture a still image and a moving image. The camera module 8280 may include a lens assembly including one or more lenses, image sensors, image signal processors, and/or flashes. The lens assembly included in the camera module 8280 may collect light emitted from a subject whose image is captured.

The power management module 8288 may manage power supplied to the electronic device 8201. The power management module 8288 may be implemented as a part of a power management integrated circuit (PMIC).

The battery 8289 may supply power to elements of the electronic device 8201. The battery 8289 may include a non-rechargeable primary cell, a rechargeable secondary cell, and/or a fuel cell.

The communication module 8290 may support establishment of a direct (wired) communication channel and/or a wireless communication channel between the electronic device 8201 and another electronic device (e.g., the electronic device 8202, the electronic device 8204, or the server 8208), and communication through the established communication channel. The communication module 8290 may include one or more communication processors that operate independently of the processor 8220 (e.g., an application processor) and support direct communication and/or wireless communication. The communication module 8290 may include a wireless communication module 8292 (e.g., a cellular communication module, a short-range wireless communication module, or a global navigation satellite system (GNSS) communication module) and/or a wired communication module 8294 (e.g., a local area network (LAN) communication module or a power line communication module). A corresponding communication module from among the communication modules may communicate with another electronic device through the first network 8298 (e.g., a short-range communication network such as Bluetooth, WiFi Direct, or infrared data association (IrDA)) or the second network 8299 (e.g., a long-range communication network such as a cellular network, the Internet, or a computer network (e.g., a LAN or a wide area network (WAN)). The various types of communication modules may be integrated into one element (e.g., a single chip), or may be implemented as a plurality of separate elements (e.g., a plurality of chips). The wireless communication module 8292 may identify and authenticate the electronic device 8201 within a communication network such as the first network 8298 and/or the second network 8299 by using subscriber information (e.g., international mobile subscriber identity (IMSI)) stored in the subscriber identification module 8296.

The antenna module 8297 may transmit a signal and/or power to the outside (e.g., another electronic device) or may receive a signal and/or power from the outside. An antenna may include a radiator including a conductive pattern formed on a substrate (e.g., a printed circuit board (PCB)). The antenna module 8297 may include one or more antennas. When the antenna module 8297 includes a plurality of antennas, an antenna suitable for a communication method used in a communication network such as the first network 8298 and/or the second network 8299 may be selected from among the plurality of antennas by the communication module 8290. A signal and/or power may be transmitted or received between the communication module 8290 and another electronic device through the selected antenna. Another component (e.g., a radio-frequency integrated circuit (RFIC)) other than the antenna may be included as a part of the antenna module 8297.

Some of the elements may be connected to one another through a communication method (e.g., a bus, a general-purpose input and output (GPIO), a serial peripheral interface (SPI), or a mobile industry processor interface (MIPI)) between peripheral devices, and may exchange signals (e.g., commands or data).

Commands or data may be transmitted or received between the electronic device 8201 and the external electronic device 8204 through the server 8208 connected to the second network 8299. The electronic devices 8202 and 8204 may be the same or different type of devices as or from the electronic device 8201. All or some of operations executed by the electronic device 8201 may be performed by at least one from among the other electronic devices 8202 and 8204, and the server 8208. For example, when the electronic device 8201 should perform certain functions or services, the electronic device 8201 may transmit a request to one or more other electronic devices to perform some or all of the functions or services, instead of directly performing the functions or services. The other electronic devices receiving the request may execute additional functions or services related to the request, and may transmit a result of the execution to the electronic device 8201. To this end, cloud computing, distributed computing, and/or client-server computing may be used.

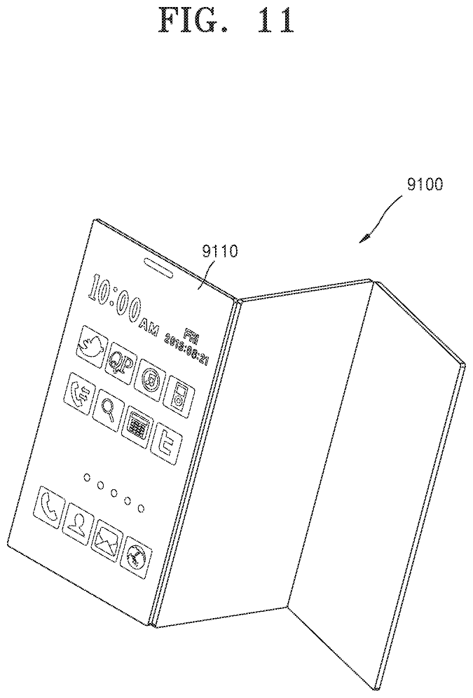

FIG. 11 is a view illustrating an example where an electronic device is applied to a mobile device, according to an example embodiment. A mobile device 9100 may include a display apparatus 9110 according to an example embodiment. The display apparatus 9110 may include the display apparatus 1 of FIGS. 1 through 9C. The display apparatus 9110 may have a foldable structure. For example, the display apparatus 9110 may be applied to a multi-foldable display. Although the mobile device 9100 is a foldable display, the mobile device 9100 may be applied to a general flat panel display.

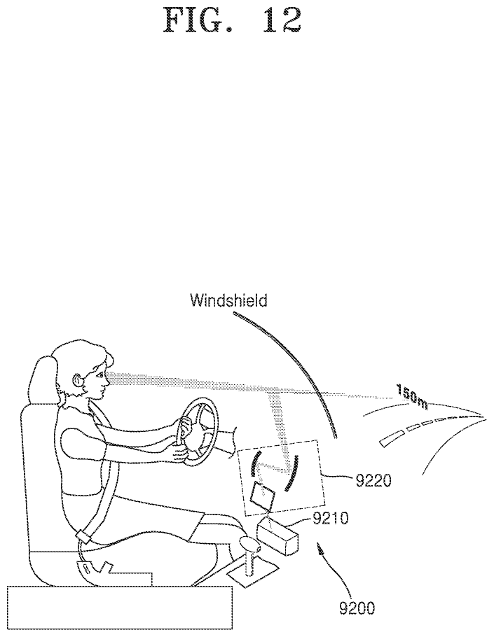

FIG. 12 is a view illustrating an example where a display apparatus is applied to a vehicle, according to an example embodiment. A display apparatus may be applied to a head-up display apparatus 9200 for a vehicle. The head-up display apparatus 9200 may include a display apparatus 9210 provided in an area of the vehicle, and at least one optical path changing member 9220 configured to change a path of light so that a driver may see an image generated on the display apparatus 9210.

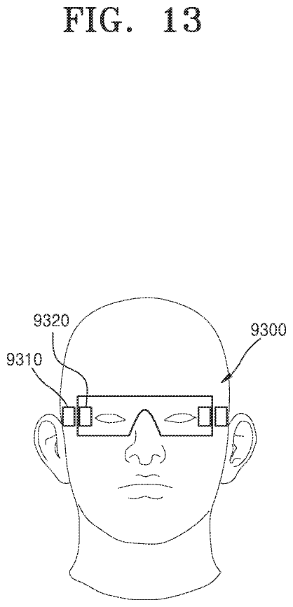

FIG. 13 is a view illustrating an example where a display apparatus is applied to augmented reality glasses or virtual reality glasses, according to an example embodiment. Virtual reality glasses 9300 may include a projection system 9310 that forms an image, and at least one element 9320 that guides an image from the projection system 9310 into a user's eyes. The projection system 9310 may include the display apparatus 1 described with reference to FIGS. 1 through 9C.

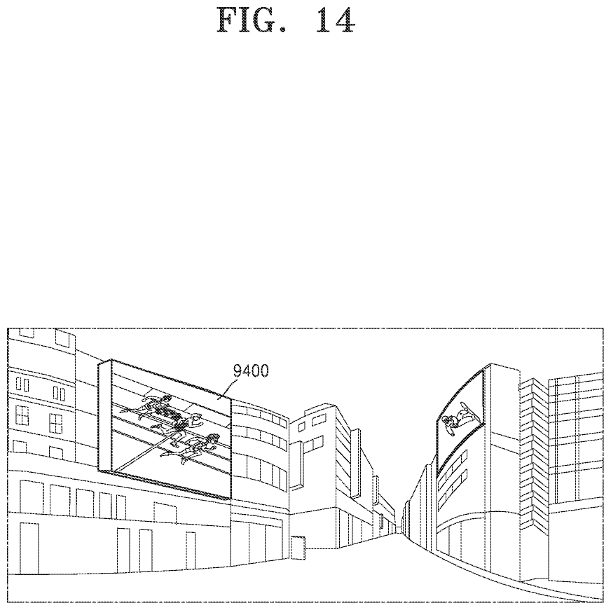

FIG. 14 is a view illustrating an example where a display apparatus is applied to a large signage, according to an example embodiment. A signage 9400 may be used for outdoor advertisement using a digital information display, and may control advertisement content or the like through a communication network. The signage 9400 may be implemented through, for example, an electronic device described with reference to FIG. 10.

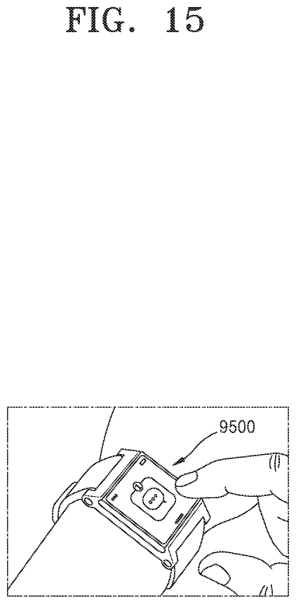

FIG. 15 is a view illustrating an example where a display apparatus is applied to a wearable display, according to an example embodiment. A wearable display 9500 may include the display apparatus 1 described with reference to FIGS. 1 through 9C, and may be implemented through an electronic device described with reference to FIG. 10.

A display apparatus according to an example embodiment may also be applied to various other products such as a rollable TV and a stretchable display.

A display apparatus and a method of manufacturing the same according to an example embodiment may include a micro light-emitting device emitting blue light and a color conversion layer having quantum dots for converting blue light into red light and green light, and may minimize quenching of the quantum dots and may increase an absorbance of the quantum dots for blue light.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a driving substrate comprising a plurality of grooves;
a plurality of micro light-emitting devices provided in the plurality of grooves, the plurality of micro light-emitting devices being configured to emit light of a first color; and
a color conversion layer provided on the plurality of micro light-emitting devices, the color conversion layer being configured to convert the light of the first color into light of at least one second color,
wherein the color conversion layer comprises:
a plurality of light blocking patterns spaced apart from the plurality of micro light-emitting devices, the plurality of light blocking patterns being spaced apart from each other on a same plane,
a nano-porous layer provided between adjacent ones of the plurality of light blocking patterns, the nano-porous layer being spaced apart from the plurality of micro light-emitting devices and comprising a plurality of nano-pores, and a plurality of quantum dots impregnated in the nano-porous layer, the plurality of quantum dots being configured to convert the light of the first color into the light of the at least one second color.

2. The display apparatus of claim 1, wherein the light of the first color comprises blue light, and the light of the at least one second color comprises red light and green light.

3. The display apparatus of claim 2, wherein the plurality of quantum dots comprise a plurality of first quantum dots configured to convert the blue light into the red light, and a plurality of second quantum dots configured to convert the blue light into the green light, and
wherein the nano-porous layer comprises a first area in which the plurality of first quantum dots are impregnated, and a second area in which the plurality of second quantum dots are impregnated.

4. The display apparatus of claim 3, wherein the nano-porous layer further comprises a third area through which the blue light is transmitted.

5. The display apparatus of claim 1, wherein the nano-porous layer comprises a plurality of nano-particles, and
wherein shapes of the plurality of nano-pores are defined by adjacent nano-particles.

6. The display apparatus of claim 1, wherein a size of each of the plurality of nano-pores is in a range from ⅕ to 1/20 of a wavelength of the light of the first color.

7. The display apparatus of claim 1, wherein a size of each of the plurality of nano-pores is in a range from 10 nm to 50 nm.

8. The display apparatus of claim 1, wherein the nano-porous layer comprises at least one of titanium oxide (TiO₂), zinc oxide (ZnO), barium peroxide (BaO₂), glass, silicon oxide (SiOx), gallium nitride (GaN), indium gallium nitride (InGaN), and a transparent polymer material.

9. The display apparatus of claim 1, further comprising a transparent layer provided between the plurality of micro light-emitting devices and the color conversion layer, the transparent layer being configured to transmit the light of the first color.

10. The display apparatus of claim 9, wherein a thermal conductivity of the transparent layer is equal to or less than 1 W/mK.

11. A method of manufacturing a display apparatus, the method comprising:
forming a color conversion layer on a plurality of micro light-emitting devices configured to emit blue light, the color conversion layer comprising a red area where the blue light is converted into red light, a green area where the blue light is converted into green light, and a blue area where the blue light is transmitted,
wherein the forming of the color conversion layer comprises:
forming, on a base substrate, a plurality of light blocking patterns for distinguishing the red area, the green area, and the blue area, and a nano-porous layer having a plurality of nano-pores, the nano-porous layer comprising a first area, a second area, and a third area respectively corresponding to the red area, the green area, and the blue area;
impregnating a plurality of first quantum dots for converting the blue light into the red light in the first area, and a plurality of second quantum dots for converting the blue light into the green light in the second area; and
covering a top surface of the nano-porous layer with a transparent layer.

12. The method of claim 11, wherein the forming of the nano-porous layer comprises:
applying a solution comprising a plurality of nano-particles to the first area, the second area, and the third area, and
performing heat treatment at a temperature of 100° C. to 300° C. for evaporation of the applied solution and sintering of the plurality of nano-particles.

13. The method of claim 12, wherein the impregnating of the plurality of first quantum dots and the plurality of second quantum dots comprises:
providing the plurality of first quantum dots to the first area of the nano-porous layer, using inkjet printing, and
providing the plurality of second quantum dots to the second area of the nano-porous layer, using inkjet printing.

14. The method of claim 11, wherein a diameter of each of the plurality of nano-pores is in a range from ⅕ to 1/20 of a wavelength of the blue light.

15. The method of claim 11, wherein a size of each of the plurality of nano-pores is in a range from 10 nm to 50 nm.

16. The method of claim 11, wherein a material of the nano-porous layer comprises at least one of titanium oxide (TiO₂), zinc oxide (ZnO), barium peroxide (BaO₂), glass, silicon oxide (SiOx), gallium nitride (GaN), indium gallium nitride (InGaN), and a transparent polymer material.

17. The method of claim 11, wherein the transparent layer has a thermal conductivity equal to or less than 1 W/mK.

18. The method of claim 11, further comprising:
arranging the plurality of micro light-emitting devices in a plurality of grooves of a driving substrate; and
locating the color conversion layer on the plurality of micro light-emitting devices,
wherein the locating of the color conversion layer comprises locating the color conversion layer so that the transparent layer faces the plurality of micro light-emitting devices.

19. The method of claim 18, wherein the arranging of the plurality of micro light-emitting devices in the plurality of grooves comprises a fluidic self-assembly method.

20. The method of claim 19, wherein the arranging of the plurality of micro light-emitting devices in the plurality of grooves comprises:
arranging the plurality of micro light-emitting devices in a plurality of grooves of a transfer substrate using the fluidic self-assembly method, and
transferring the plurality of micro light-emitting devices arranged in the plurality of grooves of the transfer substrate to the plurality of grooves of the driving substrate.
